(19) United States
(12) Patent Application Publication
(10) Pub. No.: US 2026/0036553 A1
(43) Pub. Date: Feb. 5, 2026

(54) System and Method for Resonance Ultrasound Spectroscopy Using Continuous Wave Lasers

(71) Applicant: Government of the United States, as represented by the Secretary of the Air Force, Wright-Patterson AFB, OH (US)

(72) Inventors: Matthew Cherry, Centerville, OH (US); Tyler Lesthaeghe, Beavercreek, OH (US); David Torres Reyes, Springboro, OH (US); Juan Pastrana, Dayton, OH (US); Rasheed Adebisi, Bellbrook, OH (US); Sydney Giannuzzi, Orlando, FL (US)

(21) Appl. No.: 18/788,313

(22) Filed: Jul. 30, 2024

(51) Int. Cl. G01N 29/12; G01N 29/06; G01N 29/24; G01N 29/30; H01S 5/042

(52) U.S. Cl. CPC G01N 29/12; G01N 29/0654; G01N 29/2418; G01N 29/30; H01S 5/0427; H01S 5/0428

(57) ABSTRACT

A system and method for resonance ultrasound spectroscopy using continuous wave lasers are disclosed. The system and method use a spatially and temporally modulated continuous wave laser to excite resonances in a sample. A spatial light modulator (SLM) modulates the phase of the beam spatially, which creates interference patterns in the far-field which generate an image of the high strain energy locations of the expected resonance mode shape. The image is pre-computed using a physics-based model. Once this pattern is imaged onto the surface of the sample, the temporal modulation frequency is swept. The vibrations induced in the sample are measured using a detection laser. The amplitude of vibration measured with the detection laser is measured at each frequency, and the point at which the amplitude is maximized is the resonance frequency for this specific mode shape. The elastic properties of the sample are inverted through a physics-based model.

### RIGHTS OF THE GOVERNMENT

The invention described herein may be manufactured and used by or for the Government of the United States for all governmental purposes without the payment of any royalty.

### FIELD OF THE INVENTION

The present invention relates generally to ultrasound spectroscopy and, more particularly, to a system for resonance ultrasound spectroscopy using continuous wave lasers and methods of measuring objects using resonance ultrasound spectroscopy.

### BACKGROUND OF THE INVENTION

Resonant ultrasound spectroscopy (RUS) has been used for decades for measuring elastic properties and defects in samples and components (see U.S. Pat. Nos. 5,062,296; 5,351,543; 5,355,731; 5,837,896; and EP Patent Application 0 628 811 A2). In RUS, the resonances are measured by exciting elastic vibrations in the sample, either with acoustic transducers or lasers, and measuring the vibrations using another transducer or a laser interferometer. These resonances are then related back to material properties through an inverse model. This implies that any property which has a significant effect on the resonance frequencies could potentially be measured using RUS.

Well known limitations of initial implementations of RUS include the requirement for contact with samples and limitations on the size of the sample that can be measured. To address these limitations, several authors have proposed the use of lasers to excite and detect resonances.

Previous work on laser-based resonant ultrasound spectroscopy (LRUS) have focused largely on using a pulsed laser. This does not work for materials such as epoxy or rubber, which do not resonate well. Other authors have expanded on the pulsed excitation method with improved detection systems and processing algorithms. However, there are still significant limitations when applied to non-resonant, low quality-factor (Q-factor) materials.

Elastic properties of low Q materials are of critical importance to a number of fields, including geophysics, medical (e.g., measuring the properties of bone or pharmaceuticals), and aerospace (e.g., elastic properties of composite materials). A system with low quality factor (e.g., <50) does not resonate as freely as a low damping material such as most metals and ceramics. This results in difficulties in measuring resonances for RUS.

Much of the original research on optical excitation of resonances used continuous wave (CW) lasers, rather than pulsed lasers. However, research on LRUS gravitated toward pulsed lasers due to the speed and reliability of measuring multiple resonances. The early authors did not explore spatial modulation of incident laser beam to preferentially excite resonance modes.

In parallel to LRUS, researchers looked at pulsed and CW methods of exciting ultrasonic surface waves in metals. European patent application EP1910815A2 discloses spatially resolved acoustic spectroscopy (SRAS). This involves using pulsed lasers along with a spatial light modulator (SLM) to spatially modulate the laser beam and preferentially excite surface wave modes. Other authors have shown the ability to excite surface wave modes with CW lasers by spatially and temporally modulating the laser beam. However, this has all been applied in the domain of surface wave spectroscopy and microscopy. These concepts are not believed to have been employed in the domain of LRUS. Previous implementations of LRUS are also not believed to be applicable for samples below 1 mm which also have low Q-factor.

Therefore, a need exists for improved resonance ultrasound spectroscopy systems, and for a method of resonance ultrasound spectroscopy, including systems and methods that are not limited to samples above 1 mm, and which are also applicable for samples that have low Q-factor.

### SUMMARY OF THE INVENTION

The present invention relates generally to ultrasound spectroscopy and, more particularly, to a system for resonance ultrasound spectroscopy using continuous wave lasers and methods of measuring objects using resonance ultrasound spectroscopy.

While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention, a system for the non-contact Laser-Based Resonant Ultrasound Spectroscopy (LRUS) measurement of a sample is provided. The system may comprise the following components:
a continuous wave (CW) excitation laser source that is configured to emit a laser beam to excite resonances in a sample, wherein the laser source is temporally modulated;
optional conditioning optics that are positioned between the CW laser source and the sample so that the laser beam travels through the conditioning optics;
a spatial light modulator (SLM) that is positioned between the CW laser source and the sample (the SLM will be positioned between the conditioning optics and the sample, if the conditioning optics are present) so that the laser beam travels through the conditioning optics (if present) and then to the SLM, and the SLM spatially modulates the beam;
imaging optics configured to focus an image onto a first surface of a sample, where the imaging optics are positioned between the SLM and the sample, and wherein the components are arranged so that a laser beam is configured to travel in the following sequence: from the laser source, through the conditioning optics (if present), to the SLM, through the imaging optics and then to a first surface of a sample;
a holder for holding a sample;
a device for measuring the sample displacement amplitude and phase which is located so that it is aligned with a surface of the sample; and
a computer that is in communication with the CW laser, the SLM, and the device for measuring the sample displacement amplitude and phase.

A non-contact method of Laser-Based Resonant Ultrasound Spectroscopy (LRUS) measurement of a sample is also provided. The sample has elastic properties and resonance modes and the resonance modes have corresponding natural frequencies and mode shapes, and the mode shapes have anti-nodes. The method comprises the steps of:
a) using a continuous wave (CW) laser to emit a laser beam, said beam having a wavefront;
b) using an electrical signal to temporally modulate the CW laser, said signal having a temporal modulation excitation frequency;
c) pre-computing the mode shapes of the sample using a model;
d) generating a first image displaying the anti-nodes of a pre-computed mode shape;
e) generating a second image comprising a computer-generated hologram (CGH) image of the first image;
f) using a spatial light modulator (SLM) to impose spatial modulation onto the laser wavefront;
g) focusing the beam onto a surface of the sample, wherein the first image induces vibrations at the anti-nodes of the mode shape;
h) sequentially changing the temporal modulation excitation frequency;
i) measuring the vibrations induced in the sample at the excitation frequency using an instrument, wherein the vibrations are maximized at a resonance frequency, and the instrument produces an output signal;
j) finding the frequency at which the output signal is maximized, this frequency being the resonance frequency corresponding to the mode shape;
k) changing the mode shape image to that of the next mode to be measured and repeating steps d) to j) to measure the resonance frequency for each mode; and
l) after each resonance frequency is detected, estimating the elastic properties of the sample using an inversion algorithm and the model.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a schematic diagram showing the basic components of one embodiment of a system for resonance ultrasound spectroscopy using a continuous wave laser.

FIG. 2 is a schematic diagram showing one embodiment of the step of generating a time-modulated continuous wave laser.

FIG. 3 is a schematic diagram showing another embodiment of the step of generating a time-modulated continuous wave laser.

FIG. 4 is a schematic diagram showing one embodiment of the conditioning optics.

FIG. 5 is a schematic diagram showing one embodiment of the step of imposing spatial modulation.

FIG. 6 is a schematic diagram showing another embodiment of the step of imposing spatial modulation.

FIG. 7 is a schematic diagram showing one embodiment of the imaging optics.

FIG. 8 is a schematic diagram showing another embodiment of the imaging optics.

FIG. 9 is a schematic diagram showing one embodiment of the step of measuring the sample displacement amplitude and phase.

FIG. 10 is a schematic diagram showing another embodiment of the step of measuring the sample displacement amplitude and phase.

FIG. 11 is a schematic diagram showing the details of one embodiment of the system for resonance ultrasound spectroscopy using a continuous wave laser.

FIG. 12 is a schematic diagram of a numerical simulation used to estimate mode shapes and resonance frequencies of an object.

FIG. 13A is a computer-generated perspective view image of a mode shape which represents the displacement at each location of a sample.

FIG. 13B is an image of the elastic strain energy on the sample surface.

FIG. 13C is a grayscale image of the elastic strain energy on the sample surface.

FIG. 13D is a box representing a Computer Generated Holography (CGH) algorithm.

FIG. 13E is the holography image of the grayscale image, which is the image displayed on the spatial light modulator (SLM).

FIG. 14 is a notational schematic diagram of an inversion algorithm.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity of illustration.

### DETAILED DESCRIPTION OF THE INVENTION

Elastic properties such as elastic moduli are of critical importance for predicting the behavior of engineering structures when subjected to external forces. Elastic moduli are fundamental to understanding novel materials, and measuring them is a subject of significant interest to many engineering and materials science disciplines.

The present invention relates generally to resonant ultrasound spectroscopy and, more particularly, to a system for resonant ultrasound spectroscopy using continuous wave lasers and methods of measuring the properties of objects using resonance ultrasound spectroscopy. The system measures resonance modes of objects, which are used to calculate properties of interest of the objects, such as elastic moduli. Elastic moduli are the one property of interest, but any properties which resonance modes are sensitive to could be measured with the methods discussed herein (e.g. texture, phase transition, residual stress or creep damage).

The system and method described herein can be used to measure objects of any suitable size, shape, and having any suitable properties. The terms “object” and “sample” may be used herein interchangeably. Samples are usually parallelepiped or cylindrically shaped, but can be of any other shapes. The system and method described herein can be used to measure small sized samples, as well as larger samples. The term “small”, as used herein, refers to samples having at least one dimension that is less than 1 mm.

The present invention is applicable to many different materials such as metals, ceramics, epoxy, composites, and includes materials that have low Q-factor. The quality factor (or Q-factor) is a dimensionless parameter that describes how underdamped an oscillator or resonator is. It is the ratio of the initial energy stored in the object to the energy lost in one radian of the cycle of oscillation. The term “low quality factor”, as used herein, refers to a Q-factor of less than 50.

Physical materials from which objects are made have elastic properties which define how the object will deform given an external force or load. The elastic deformation is generally determined by the linear elastic properties, usually the 2^{nd} order elastic modulus (or multiple moduli in the case of anisotropic materials). In cases where the external force or load is dynamic (changing in time), the mass density is also important in determining the elastic deformation of the object. Lastly, the geometry of the object is also important in understanding the elastic deformation in response to external loads.

The elastic “deformation” of the object can also be referred to as “deflections” or “displacements”. These terms may be used herein interchangeably. When the deformation is dynamic, it is referred to as “vibration”.

The system and method described herein pertain to measuring the elastic properties of an object made from a specific material by observing the elastic deformation of the object under an external load. The external load in the method described herein is provided by a continuous wave (CW) laser, which may also be referred to as the “first laser” or the “excitation laser”.

### The System

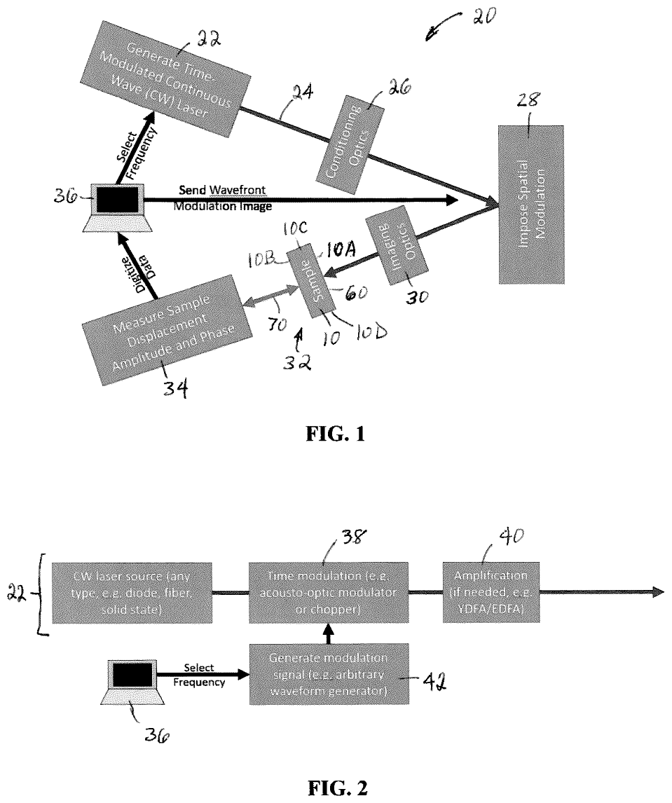

FIG. 1 shows the basic components of one non-limiting embodiment of a system for the non-contact Laser-Based Resonance Ultrasound Spectroscopy (LRUS) measurement of a sample using a continuous wave laser (“the system”). The system 20 may comprise the following components: a continuous wave (CW) excitation laser source (or “first laser”) 22, optional conditioning optics 26, a spatial light modulator (SLM) 28, imaging optics 30, a location 32 for a sample 10, a device 34 for measuring the sample displacement amplitude and phase, and a computer 36. The system is assembled from optical components which are aligned specifically to generate the mode shape pattern on a surface of the sample as will be described herein.

The sample 10 has a plurality of surfaces, including a first surface 10A, a second surface 10B, and other surfaces. The other surfaces can be designated 10C, 10D, etc. The first surface 10A of the sample 10 is the surface of the sample that is contacted by the laser beam from the continuous wave (CW) laser source 22. The second surface 10B can be on any suitable surface of the sample, including but not limited to the opposite side of the sample 10 from the first surface 10A.

The object, having finite geometry and elastic properties as well as mass density, has characteristic resonance modes at which the object vibrates. The resonance modes have a resonance frequency and a mode shape. The resonance frequency is the frequency where, when an external load is applied at such frequency, the vibration in the object is maximized. The mode shape comprises displacements at each point in the sample.

This system 20 uses a temporally modulated continuous wave (CW) laser 22 to emit a laser beam 24 to excite mechanical resonances in the sample 10. The CW laser 22 may comprise any suitable type of continuous wave (CW) laser including, but not limited to one of the following: a diode laser which is a type of free-space laser, a fiber-coupled laser, or a different form of free-space laser from a diode laser. The different form of free-space laser may include, but is not limited to one of the following: a gas laser, a solid state laser, or a dye laser.

The CW laser beam has a wavefront which determines the amplitude and phase of the light at each point in a plane normal to the propagation direction of the laser beam. The “propagation direction” or “axis” of the laser determines the line in which the laser light propagates until obstructed or redirected. The amplitude and phase can be modulated both temporally (in time) as well as spatially by changing the amplitude and phase at points in the wavefront.

FIG. 2 shows the temporal (or time) modulation of the laser beam 24. The CW laser 22 can be temporally modulated using various different combinations of equipment. In some cases, when the excitation laser source 22 is a free-space laser, the laser source may be temporally modulated externally with one of an acousto-optic modulator or a chopper 38 that is positioned so that the laser beam 24 travels through the acousto-optic modulator or chopper 38. In other cases, the excitation laser source 22 may be a fiber-coupled laser source, and the laser source may be free-space coupled and temporally modulated externally with one of an acousto-optic modulator or a chopper 38. In other cases, the excitation laser source 22 may be a laser diode, and the laser source may be temporally modulated by modulating at least one of power or current to the laser diode.

The amplitude of the CW laser can be modulated temporally by changing the frequency content of a signal controlling the amplitude of the CW laser. An electrical signal can be supplied from an external source to control the temporal modulation of the laser. The signal can be supplied by any external equipment which supplies arbitrary signals or waveforms. The electrical signal can be sent to the laser, the acousto-optic modulator, or to the chopper. In some cases, an arbitrary waveform generator 42 is used to control the temporal modulation of the laser. This signal can be one of a sine wave signal at a specific frequency, a signal which contains multiple frequencies, a transistor-transistor logic (TTL), or another signal that can control the frequency content of the signal. For instance, a sine wave at a specific frequency can create a sine wave modulation in the power of the continuous wave laser. The frequency content of the time-modulated laser should be controlled by the computer 36 so that it can be changed during a measurement. If the signal has frequency content which corresponds to a resonance frequency of a resonance mode of the object 10, the object will vibrate with a maximum displacement.

FIGS. 2 and 3 show that in some cases, it may be desirable to increase the power of the laser and amplify the laser beam. In such cases, an amplifier 40 may be positioned so that the excitation laser beam 24 travels through the amplifier 40 that amplifies the laser beam before or after the laser is temporally modulated. Any suitable amplifier can be used for this purpose. Suitable examples of amplifiers include, but are not limited to a 1064 nm Ytterbium-doped fiber amplifier (YDFA), and an erbium-doped fiber amplifier (EDFA). The amplifier 40 can be integrated into the system in several different ways. The amplifier 40 may be fiber coupled to the laser 22. There are a number of ways to fiber couple a laser, but most rely on a lens to focus the beam 24 onto the fiber core so that the beam is traveling in the fiber inside the fiber amplifier. For example, if the laser source is a free-space laser and the amplifier is a fiber amplifier, the free-space laser may be coupled into an optical fiber using a focusing lens and then injected into the fiber amplifier through a coupling port. The amplifier 40 may have an output fiber, and the laser in the output fiber is coupled into free space and collimated using a lens.

The optional conditioning optics 26 (if present) are positioned between the CW laser source 22 and the sample 10 so that the laser beam 24 travels through the conditioning optics 26. The conditioning optics 26 may be configured to expand the beam 24 and rotate polarization (1/2 waveplate) for spatial modulation. In some cases, the conditioning optics 26 may also spatially filter the beam 24 if the wavefront is not good (i.e., if the wavefront is non-Gaussian). If a fiber amplifier is used, however, it is typically not necessary to spatially filter the beam 24 because the beam is mostly Gaussian coming out of the fiber amplifier. The optional conditioning optics 26 may comprise at least one lens and a component that causes the beam wavefront to be Gaussian and to be of a size that utilizes a maximum number of pixels on the SLM. In cases in which it is necessary to spatially filter the beam 24, the conditioning optics 26 may comprise a 4-f optical relay with a precision pin hole to remove high-frequency spatial noise from the wavefront.

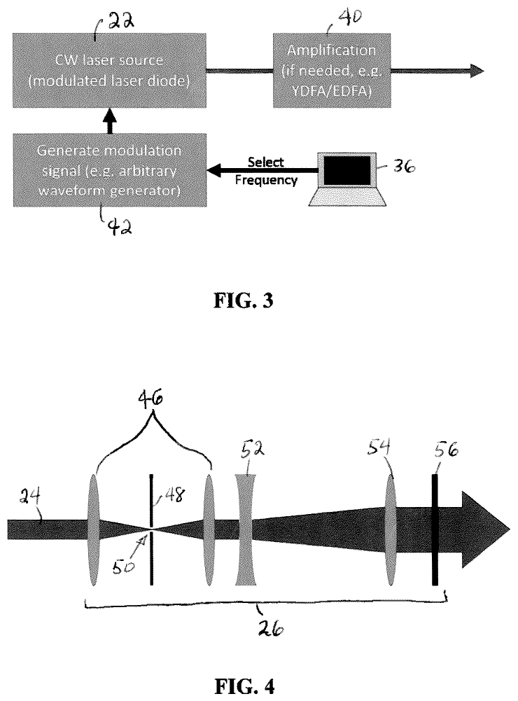

FIG. 4 shows one non-limiting embodiment of the conditioning optics 26. The components of the conditioning optics 26 shown in FIG. 4 comprise: a (first) 4-f optical relay 46, a member 48 with a pinhole 50 therein, an expander 52, a collimator 54, and a 1/2 waveplate 56. The 4-f optical relay with the pinhole 50 may be referred to as a spatial filter. As discussed above, the spatial filter is optional in cases in which the wavefront is Gaussian. However, a spatial filter can also be used for the purpose of expanding the beam 24 to take advantage of more pixels on the SLM. The polarization of the laser beam 24 can be rotated (1/2 waveplate) for spatial modulation.

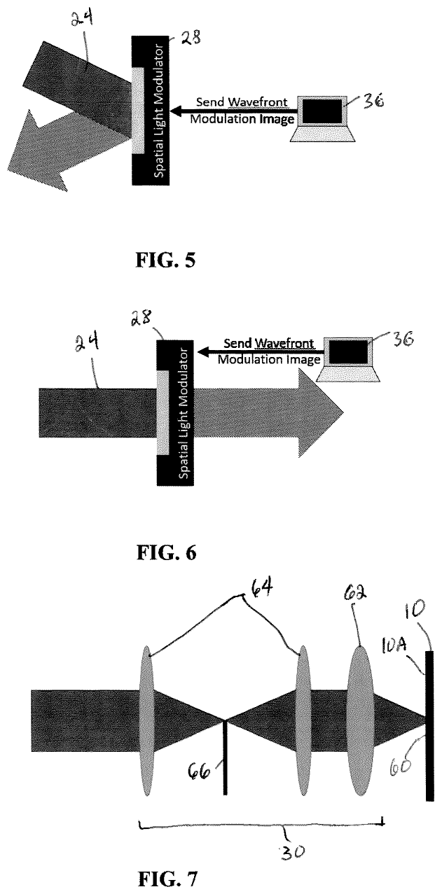

FIG. 1 shows that the spatial light modulator (SLM) 28 is positioned between the conditioning optics 26 and the sample 10 so that the laser beam 24 travels through the conditioning optics 26 and then to the SLM 28. If conditioning optics are not used, the SLM is positioned between the laser source 22 and the sample 10. The SLM 28 spatially modulates the beam 24. The SLM 28 can be any suitable spatial light modulator. In some cases, as shown in FIGS. 1 and 5, the spatial light modulator (SLM) 28 may be a reflective SLM having a surface and the beam 24 reflects off the surface of the SLM to impose at least one of phase and amplitude modulation. In other cases, as shown in FIG. 6, the spatial light modulator (SLM) 28 may be a transmissive SLM and the beam 24 passes through the SLM to impose at least one of phase and amplitude modulation.

The spatial light modulator (SLM) can spatially modulate the amplitude and phase of the wavefront of the CW laser. Traditional laser beams often have a Gaussian wavefront where the amplitude of light decays exponentially away from the axis of the laser beam. Spatial modulation causes the laser wavefront to show an image other than a Gaussian function on the wavefront. In the system and method described herein, the phase may be modulated so that the wavefront takes on a computer-generated hologram (CGH) image as described in further detail herein.

In some cases, the SLM may have a liquid crystal display (LCD) with pixels that retard the laser light at the spatial location of each of the pixels. The LCD is mounted in front of a reflective surface so that the laser reflects after passing through the LCD. The wavefront that reflects from the LCD is said to be spatially modulated, with a different phase at each location on the wavefront determined by individual voltages applied to each LCD pixel. Other suitable versions of spatial modulation exist.

After the wavefront has been modulated by the SLM, and the laser either propagates a long distance or is imaged through a lens, referred to herein as the imaging optics or “imaging lens”, and a first image (or “strain energy image”) is displayed by the laser. In the system and method described herein, this results in the laser having high amplitude in regions of high strain energy and low amplitude in regions of low strain energy. The combination of spatially modulating the wavefront to image areas of high strain energy on the object surface, and temporally modulating the laser amplitude at the resonance frequency of the mode shape which generated the strain energy image, results in much stronger vibrations of the object than simply modulating the laser in time.

The imaging optics 30 are configured to focus the strain energy image 60 onto a first surface 10A of a sample 10. The imaging optics 30 are positioned between the SLM 28 and the sample 10. The components are arranged so that a laser beam 24 is configured to travel in the following sequence: from the laser source 22, through the amplifier 40 (that is, unless the amplifier 40 is considered to be part of the laser source 22), through the conditioning optics 26 (if present), to the SLM 28, through the imaging optics 30 and then to a first surface 10A of a sample 10. The imaging optics 30 may comprise at least one lens. FIG. 8 shows that in one case, the imaging optics 30 comprise an imaging lens 62 that is configured to focus the strain energy image (in the form of a spatial pattern) 60 onto a sample surface 10A. The image is configured to remove unnecessary portions of the wavefront in the wavefront modulation step.

FIG. 7 shows that, in other cases, the imaging optics 30 may comprise: an imaging lens 62 that is positioned closest to the first surface 10A of a sample 10, a 4-f optical relay 64 that is configured to generate a Fourier transform positioned furthest from the sample surface 10A, and a single-sided filter 66 that is configured to remove unnecessary portions of the wavefront positioned between the components of the 4-f optical relay 64, which is used to focus the image 60 onto the sample surface. In other cases, the imaging optics 30 may comprise: an imaging lens 62 that is positioned closest to the first surface 10A of a sample, a 4-f optical relay 64 that is configured to generate a Fourier transform positioned furthest from the sample surface, and an annular aperture obstruction target (conventional and not shown) that is configured to remove unnecessary portions of the wavefront positioned between the 4-f optical relay 64 and the imaging lens 62. Suitable annular aperture obstruction targets are commercially available from a number of companies, such as Thorlabs, Newton, NJ, USA. The 4-f optical relays in the imaging optics 30 may be referred to as a “second” 4-f optical relay, if a 4-f optical relay is included in the conditioning optics 26.

The location for a sample 10 can, in some cases, comprise a holder 32 for the sample. Any suitable sample holder can be used.

The CW laser light 24, when directed to a surface of the object, sample 10, is partially or fully absorbed by the sample. When the light is absorbed, it is converted to heat. Thermo-elastic expansion causes the sample 10 to expand when heated. Thus, the sample 10 expands in the area where the CW laser light 24 is applied.

The mode shapes of the resonance modes of the object 10 have associated with them areas of high and low elastic strain energy. The elastic strain energy is a measure of the stored energy in the object when it vibrates. Thermo-elastic excitation preferentially excites areas of high elastic strain energy, and causes less deformation when applied in areas of low strain energy. Thus, when a CW laser light (or beam) is absorbed on an object surface, the object will undergo maximum vibration when the laser light is applied at the resonance frequency of the resonance mode and at the areas of high elastic strain energy in the mode shape.

Vibrations in the object 10 are detected with a suitable device or method for detection of small displacements in a sample at the required frequency range. The device 34 shown in FIG. 1 for measuring the sample displacement amplitude and phase can comprise any device that is suitable for this purpose. Suitable devices 34 include, but are not limited to detection laser sources, such as a laser interferometer or a laser Doppler vibrometer. An interferometer is a device that uses a “second laser” or “detection laser” which reflects off a surface of the object 10. The reflected light is compared to the outgoing light, and interference patterns are used to measure the displacements on the surface of the object. A vibrometer operates with a similar principle, but measures the Doppler shift of the light to calculate the particle velocity at the point where the second laser intersects with a surface of the sample. In a vibrometer, a detection laser beam 70 that comes out from the vibrometer 34, reflects off a surface of the sample 10, such as the second surface 10B, and goes back into the vibrometer 34. The vibrometer 34 produces a signal that represents the displacement or velocity at the points where the vibrometer detection laser beam 70 illuminates the second surface 10B.

The detection laser beam can be moved to contact different points on the surface of the sample 10 to map the displacement at each point on the surface. As discussed earlier, the mode shape consists of displacements at each point in the object. If the displacement is measured at each point on the surface of a sample, the mode shape on that surface can be measured. This can help verify that the proper mode was excited by the excitation laser.

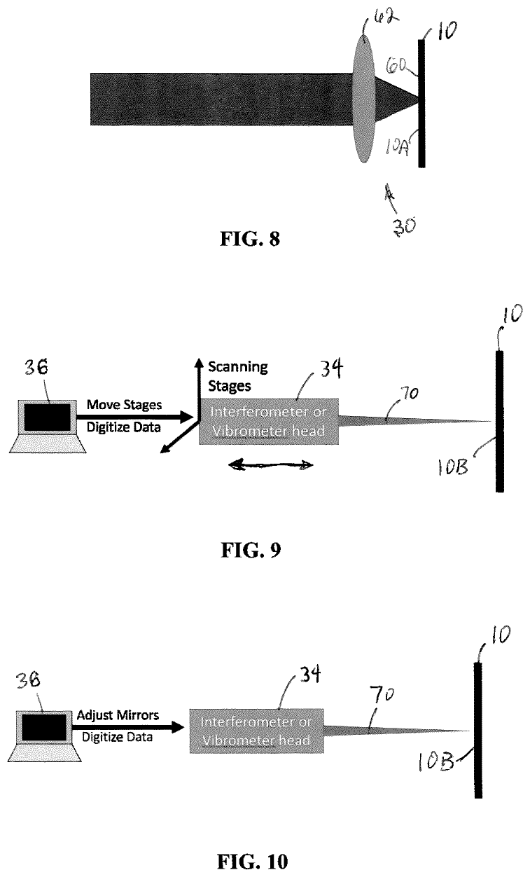

FIG. 9 shows (by the double-headed arrow) that the output aperture of the detection laser source 34 may be configured to be movable to collect data at different points on the surface of the sample 10. The device 34 for measuring the sample displacement amplitude and phase may be located so that it may measure any surface of the sample including the first surface 10A (with modifications to the setup described herein), the second surface 10B, and other surfaces 10C, 10D, etc. In the embodiment shown in FIG. 1, the device 34 is aligned with the second surface 10B of the sample 10 so that it measures the sample displacement amplitude and phase at the second surface 10B. The average spectrum and mode shape images are computed (to verify mode excitation).

FIG. 10 shows that, in some embodiments, the system 20 may comprise a system of motorized mirrors positioned along the path of the detection laser beam 70 to collect data at different points on the surface of the sample 10. The mirror tilts may be adjusted to move the laser beam to different spots on the sample surface.

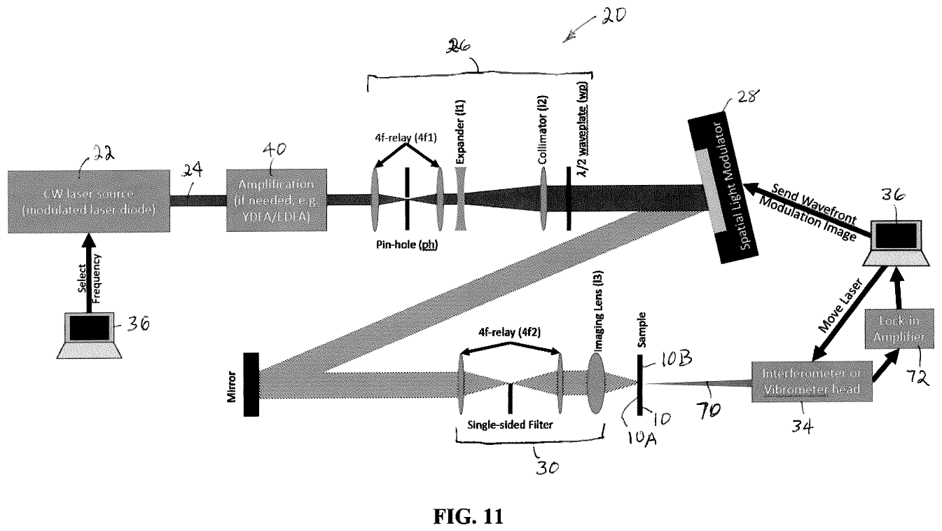

FIG. 11 shows that the output signal of the detection laser source 34 may be fed into a lock-in amplifier. The lock-in amplifier 72 allows for very low-level signals to be detected in otherwise noisy signals, making it ideal for this measurements system. The amplitude of vibration measured with the vibrometer 34 is measured while changing the frequency content of the time-modulated laser, and the signal from the vibrometer 34 is sent to the lock-in amplifier 72. The frequency at which the amplitude is maximized is the resonance frequency for this specific mode shape. It should be understood that there are other ways of finding the maximum of the output signal, and that the system is not limited to using a lock-in amplifier.

The computer 36 is in operative communication with the laser 22, the spatial light modulator (SLM) 28, and the device 34 for measuring the sample displacement amplitude and phase such as the interferometer or vibrometer. The computer 36 may perform one or more of the following tasks: control the frequency content of temporal modulation; shift excitation frequency; generate the initial estimate of mode shapes; calculate mode shape images using a model; calculate phase and/or amplitude display for spatial modulation; calculate a hologram to display on the SLM; control the SLM; collect amplitude/phase of sample vibrations measured with the detection method; move the detection laser, if the detection laser is being moved; calculate resonance frequencies; and perform an inversion on properties using the model.

### The Method

A non-contact method of Laser-Based Resonant Ultrasound Spectroscopy (LRUS) measurement of a sample is also provided herein. The method may use the system 20 described above.

The sample 10 may have any of the properties described above. In some cases, the sample 10 may be below 1 mm in size and have a low Q-factor. The sample has a geometry, boundary conditions, elastic properties, mass density, and resonance modes. The resonance modes have corresponding natural frequencies and mode shapes, and the mode shapes have anti-nodes.

The anti-nodes of the mode shapes are generally areas on the surface of the sample with high amplitudes of vibration. The anti-nodes may also be defined as areas with high strain energy. When mode shapes are excited at the natural frequency associated with the mode shape, these areas have the highest thermo-elastic response. Thus, since the laser is exciting the sample in the thermo-elastic regime, the anti-nodes of the mode shape are the ideal locations to excite specific resonance modes.

To enhance absorption of laser light, a coating can be applied to the surface of the sample 10. The coating can be any suitable material which absorbs the specific laser wavelength used. The coating may (though not necessarily) be matched to the object acoustically by using materials with similar acoustic impedance. Acoustic impedance is a measurement of the opposition that the material presents to acoustic flow resulting from acoustic pressure applied to the material. The acoustic impedance of a material is a function of the mass density and the elastic moduli. Coatings are useful in situations where the material being tested (e.g., silicon) is not absorptive to the excitation laser wavelength. The coating provides the surface of the sample 10 contacted by the laser beam with the ability to absorb the laser energy and create a temperature rise. Some sample materials, such as metals, are absorptive to the excitation laser wavelength, and do not require a coating.

The non-contact method of Laser-Based Resonant Ultrasound Spectroscopy (LRUS) measurement of a sample may generally comprise the steps of:
a) using a continuous wave (CW) laser to emit a laser beam, wherein the beam has a wavefront;
b) using an electrical signal to temporally modulate the CW laser, said signal having a temporal modulation excitation frequency;
c) pre-computing the mode shapes of the sample using a model, wherein the mode shapes have anti-nodes;
d) generating a first image displaying the anti-nodes of a pre-computed mode shape;
e) generating a second image comprising a computer-generated hologram (CGH) image of the first image;
f) using a spatial light modulator (SLM) to impose spatial modulation onto the laser wavefront;
g) focusing the beam onto a surface of the sample, wherein the first image induces vibrations at the anti-nodes of the mode shape;
h) sequentially changing the temporal modulation excitation frequency;
i) measuring the vibrations induced in the sample at the excitation frequency using an instrument, wherein the vibrations are maximized at a resonance frequency, and the instrument produces an output signal;
j) finding the frequency at which the output signal is maximized, this frequency being the resonance frequency corresponding to the mode shape;
k) changing the mode shape image to that of the next mode to be measured and repeating steps d) to j), to measure the resonance frequency for each mode;
l) after each resonance frequency is detected, estimating the elastic properties of the sample using an inversion algorithm and the model.

The steps of the method can be carried out in any suitable order, and it is also possible that one or more of the steps can be carried out simultaneously. In some cases, one or more of the steps described herein may be optional, and may be omitted.

The step a) of using a continuous wave (CW) laser 22 to emit a laser beam 24 is described above in conjunction with the description of the system 20, and with reference to FIGS. 1 and 11. The laser beam 24 has a wavefront which is the surface of constant phase of the electromagnetic wave that makes up the beam.

The step b) of temporally modulating the CW laser 24 is described above in conjunction with the description of the system 20 and with reference to FIG. 2. An electrical signal having an excitation frequency may be used to temporally modulate the CW laser 22. The temporal modulation is defined by a harmonic signal in the form of at least one frequency.

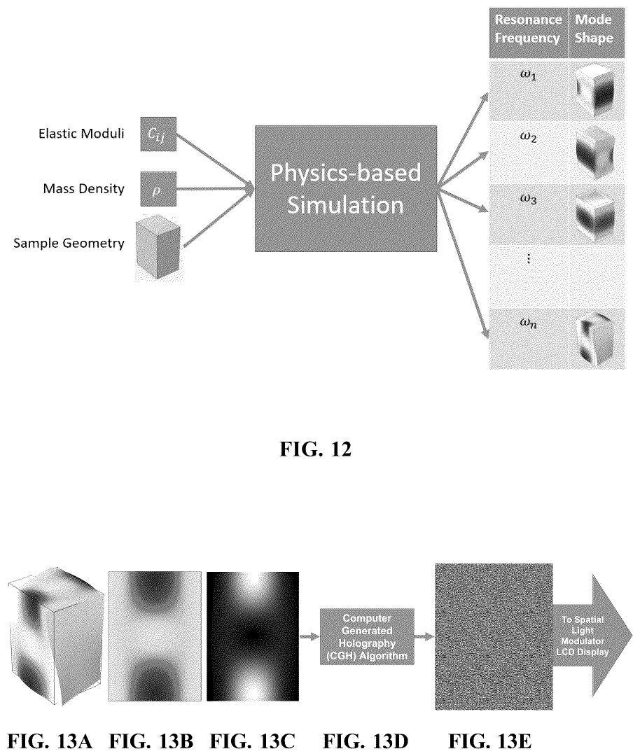

The step c) of using a model to pre-compute the estimated mode shapes of a sample involves using a physics-based forward model with an estimate of the elastic properties of the sample. This step is shown in FIG. 12. The model (i.e., the physics-based simulation or numerical simulation) takes material properties such as elastic moduli Cᵢⱼ and mass density ρ as well as the geometry and boundary conditions of the sample as inputs. It then solves for the elastic behavior of the sample using a numerical simulation technique (the physics-based simulation), and predicts the elastic resonance frequencies ω₁ to ωₙ and mode shapes of the sample as outputs. The mode shapes give the sample displacements at each resonance frequency.

The model solves the equations of elasticity on a computational domain, which is defined by the geometry of the sample. Numerical methods are often employed to solve the equations. Finite element analysis, Rayleigh-Ritz and finite difference methods are examples of numerical methods for solving the elasticity equations on a computational domain, but other methods also exist. In some cases, the model is solved using a numerical simulation where the spatial domain is discretized using global interpolation functions (such as Rayleigh-Ritz method). In other cases, the model is a numerical simulation where the spatial domain is discretized using local interpolation functions (such as Finite Element Method). In still other cases, the geometry of the sample is simple enough to allow for analytical calculation of resonance frequencies and mode shapes (e.g. Euler-Bernoulli beam theory).

The step d) involves generating a first image displaying the anti-nodes of the pre-computed mode shape comprises generating a grayscale image of the strain energy. FIG. 13A shows an example of one of the estimated mode shapes computed with the model that provides displacements at each point in the sample. These displacements can be used to calculate the elastic strain energy on a surface of the sample (FIG. 13B). The strain energy at each point on the surface can be converted into a grayscale image shown in FIG. 13C, which is referred to herein as “the first image” or the “strain energy image”.

The step e) of generating a second image comprising a computer-generated holography (CGH) image of the first image is made by calculating the CGH image from the grayscale mode shape image. The first image shown in FIG. 13C is converted to a hologram shown in FIG. 13E, which is “the second image” using the step of computer-generated holography (CGH) shown in FIG. 13D. CGH can be any technique for generating a hologram of an image. Examples of computer-generated holography (CGH) are described in U.S. Pat. No. 10,416,609 and 10,591,871, both in the name of Pellizzari, et al. The hologram is related to the spatial Fourier transform of the first image shown in FIG. 13C. In the context of coherent light sources, CGH can be used to modulate the wavefront spatially. In the case of the present method, the image that is used to modulate the laser wavefront spatially is the second image shown in FIG. 13E.

The step f) comprises using a spatial light modulator (SLM) 28 to impose spatial modulation onto the laser wavefront. This step is described above in conjunction with the description of the system 20, and with reference to FIGS. 1, 5-6, and 11.

The step g) of focusing the beam 24 onto a surface 10A of the sample 10, wherein the first image 60 induces vibrations at the anti-nodes of the mode shape is described above in conjunction with the description of the system 20, and with reference to FIGS. 1, 7-8, and 11.

The combination of spatially modulating the wavefront to image areas of high strain energy on the object 10 surface, and temporally modulating the laser amplitude at the resonance frequency of the mode shape which generated the strain energy image, results in much stronger vibrations than simply modulating the laser in time. When the CW laser light is absorbed on the surface of the object 10, the object will undergo maximum vibration when the laser is applied at the resonance frequency of the resonance mode and at the areas of high elastic strain energy in the mode shape. This generates a thermoelastic strain at the high-strain locations of the mode shape, thus preferentially exciting these mode shapes.

In step h), once the first image 60 shown in FIG. 13C is imaged onto the surface of the sample 10, the temporal modulation frequency is sequentially changed using a function generator 42 (shown in FIGS. 2 and 3). As discussed above, an arbitrary waveform generator 42 is initially used to temporally modulate the CW laser. In this step, the frequency of modulation is changed until the sample 10 reaches a maximum vibration.

The step i) of measuring the vibrations induced in the sample 10 at the frequency of excitation using an instrument comprises using a device 34 such as a detection laser source, such as a laser interferometer or a laser Doppler vibrometer to measure the vibrations.

In step j), the detection method is used to measure vibrations in the sample while the frequency content of the excitation laser is changed. Vibrations will be at a maximum when the excitation laser is modulated with frequency content that contains the resonance frequency of the mode shape imaged onto the surface with the excitation laser. The frequency at which the vibrations are maximized is referred to as the “measured resonance frequency” of the mode shape imaged using the SLM.

In step k), a suitable number of mode shapes may be imaged onto a surface of the sample, and the measured resonance frequency for each mode is determined. Steps d) to j) are repeated for a sufficient number of modes to perform the inversion algorithm for elastic properties. An example of a suitable number might be between five and ten or twelve (e.g., eight) measured resonance frequencies for each elastic modulus value to be measured. Other metrics can be used to determine the number of measured resonance frequencies needed.

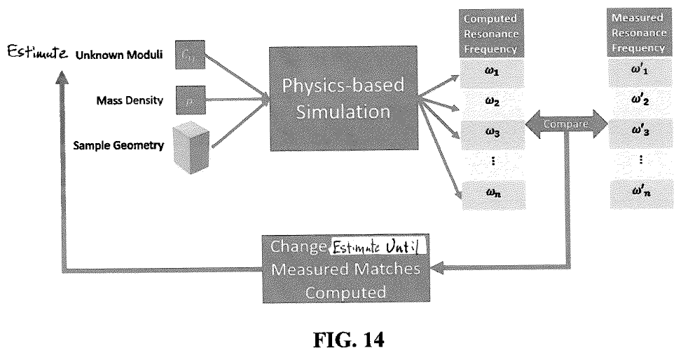

After each resonance frequency is detected, the step l) comprises estimating the elastic properties of the sample using an inversion algorithm and the model. Once a suitable number of measured resonance frequencies are collected, the model is used to estimate the elastic moduli of the material. This is referred to as an “inverse problem”. A simplified schematic of one embodiment of an inverse problem is shown in FIG. 14. The elastic moduli input to the model are changed until the measured resonance frequencies match the resonance frequencies computed with the model. Any suitable algorithm for the inverse problem can be used.

The system and method described herein are applicable in any field where non-contact measurement of elastic properties of materials is critical, such as high-temperature propulsion components, leading edge materials, and materials for use in irradiated environments.

The system for resonance ultrasound spectroscopy described herein can provide a number of advantages. It should be understood, however, that these advantages need not be required unless they are set forth in the appended claims.

This invention represents an improvement to existing state of the art in LRUS measurement systems. The primary advantage this system has over others is that it incorporates a spatial light modulator, which allows for preferential excitation of specific resonance modes. This is an improvement over other implementations in that it allows the use of CW lasers to excite very high-order resonances, allowing for the use of a highly sensitive lock-in amplifier and improved signal-to-noise ratio. It also allows for optical excitation of resonance modes in materials with lower Q-factor than previously achievable.

This invention allows for rapid qualification and testing of new materials. Elastic properties are a fundamental property of any material, and rapid measurement enables iterative design of new materials, resulting in improved performance and sustainability of aircraft and other systems. Many companies manufacturing new materials have research and development (R&D) departments that investigate novel materials for improved performance. This system could be used in these departments for rapid assessment of the properties of novel materials. Furthermore, this system could have application in rapid quality assessment of newly manufactured components if applied on the component scale.

As used herein, an element or step recited in the singular and preceded with the word “a” or “an” should be understood as including the plural of such elements or steps, unless the plural of such elements or steps is specifically excluded.

The disclosure of all patents, patent applications (and any patents which issue thereon, as well as any corresponding published foreign patent applications), and publications mentioned throughout this description are hereby incorporated by reference herein. It is expressly not admitted, however, that any of the documents incorporated by reference herein teach or disclose the present invention.

It should be understood that every maximum numerical limitation given throughout this specification includes every lower numerical limitation, as if such lower numerical limitations were expressly written herein. Every minimum numerical limitation given throughout this specification includes every higher numerical limitation, as if such higher numerical limitations were expressly written herein. Every numerical range given throughout this specification includes every narrower numerical range that falls within such broader numerical range, as if such narrower numerical ranges were all expressly written herein.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A system for the non-contact Laser-Based Resonant Ultrasound Spectroscopy (LRUS) measurement of a sample, which sample has a plurality of surfaces, including a first surface, said system comprising the following components:
a continuous wave (CW) excitation laser source that is configured to emit a laser beam to excite resonances in a sample, wherein said laser source is temporally modulated;
a spatial light modulator (SLM) that is positioned between the CW laser source and the sample so that the laser beam travels to the SLM and said SLM spatially modulates said beam;
imaging optics configured to focus an image onto a first surface of a sample, where said imaging optics are positioned between the SLM and the sample, and wherein the components are arranged so that a laser beam is configured to travel in the following sequence: from the laser source, to the SLM, through the imaging optics and then to a first surface of a sample;
a holder for holding a sample;
a device for measuring the sample displacement amplitude and phase which is located so that it is aligned with a surface of the sample; and
a computer that is in communication with the CW laser, the SLM, and the device for measuring the sample displacement amplitude and phase.

2. The system of claim 1 wherein the excitation laser source comprises one of the following: a diode laser which is a type of free-space laser, a fiber-coupled laser, or a different form of free-space laser from a diode laser.

3. The system of claim 2 wherein the different form of free-space laser is one of the following: a gas laser, a solid state laser, or a dye laser.

4. The system of claim 2 wherein the excitation laser source is a free-space laser, and the laser source is temporally modulated externally with one of an acousto-optic modulator or a chopper that is positioned so that the laser beam travels through said acousto-optic modulator or chopper.

5. The system of claim 2 wherein the excitation laser source is a fiber-coupled laser source, and the laser source is free-space coupled and temporally modulated externally with one of an acousto-optic modulator or a chopper.

6. The system of claim 2 wherein the excitation laser source is a laser diode, and the laser source is temporally modulated by modulating at least one of power or current to the laser diode.

7. The system of claim 1 wherein the excitation laser source receives a temporal modulation signal to temporally modulate the laser source, and the temporal modulation signal is provided by an arbitrary waveform generator that is in communication with the laser source.

8. The system of claim 2 wherein further comprising an amplifier positioned so that the excitation laser beam travels through the amplifier that amplifies the laser beam before or after the laser is temporally modulated.

9. The system of claim 8 wherein the excitation laser source is a free-space laser and the amplifier is a fiber amplifier that has an output fiber where laser energy emerges from the amplifier, which fiber amplifier is coupled into an optical fiber using a focusing lens and then injected into the fiber amplifier through a coupling port.

10. The system of claim 8 wherein the amplifier has an output fiber, and the laser in the output fiber is coupled into free space using a lens.

11. The system of claim 1 further comprising conditioning optics positioned between the CW laser source and the sample, wherein the conditioning optics are configured to expand the beam and rotate polarization (1/2 waveplate) for spatial modulation.

12. The system of claim 1 further comprising conditioning optics positioned between the CW laser source and the sample, wherein the excitation laser beam has a wavefront and the conditioning optics comprise a 4-f optical relay with a spatial filter to remove high-frequency spatial noise from the wavefront.

13. The system of claim 1 wherein the spatial light modulator (SLM) is a reflective SLM having a surface and the beam reflects off the surface of the SLM to impose at least one of phase and amplitude modulation.

14. The system of claim 1 wherein the spatial light modulator (SLM) is a transmissive SLM and the beam passes through the SLM to impose at least one of phase and amplitude modulation.

15. The system of claim 1 wherein the imaging optics comprise an imaging lens configured to focus an image onto a sample surface.

16. The system of claim 1 wherein the imaging optics comprise: an imaging lens that is positioned closest to the first surface of a sample, a 4-f optical relay that is positioned furthest from the sample surface, and a single-sided filter that is configured to remove unnecessary portions of the wavefront positioned between the 4-f optical relay and the imaging lens.

17. The system of claim 1 wherein the imaging optics comprise: an imaging lens that is positioned closest to the first surface of a sample, a 4-f optical relay that is positioned furthest from the sample surface, and an annular aperture obstruction target that is configured to remove unnecessary portions of the wavefront positioned between the 4-f optical relay and the imaging lens.

18. The system of claim 1 wherein the device for measuring the sample displacement amplitude and phase comprises one of a laser interferometer or laser vibrometer, said interferometer or vibrometer having a detection laser and an output aperture.

19. The system of claim 18 wherein the output aperture of the detection laser source is configured to be movable to collect data at different points on a surface of the sample.

20. The system of claim 18 further comprising a system of motorized mirrors positioned along the path of the detection laser beam to collect data at different points on the surface of the sample.

21. The system of claim 1 wherein the device for measuring the sample displacement amplitude and phase is a detection laser, and the surface with which it is aligned is the same as the first surface, and beam-splitting optics are used to separate the excitation laser and detection laser.

21. A non-contact method of Laser-Based Resonant Ultrasound Spectroscopy (LRUS) measurement of a sample, which sample has elastic properties and resonance modes and the resonance modes have corresponding natural frequencies and mode shapes, said mode shapes having anti-nodes, wherein the method comprises the steps of:
a) using a continuous wave (CW) laser to emit a laser beam, said beam having a wavefront;
b) using an electrical signal to temporally modulate the CW laser, said signal having a temporal modulation excitation frequency;
c) pre-computing the mode shapes of the sample using a model;
d) generating a first image displaying the anti-nodes of the pre-computed mode shape;
e) generating a second image comprising a computer-generated holography (CGH) image of the first image;
f) using a spatial light modulator (SLM) to impose spatial modulation onto the laser wavefront;
g) focusing the beam onto a surface of the sample, wherein the first image induces vibrations at the anti-nodes of the mode shape;
h) sequentially changing the temporal modulation excitation frequency;
i) measuring the vibrations induced in the sample at the excitation frequency using an instrument, wherein the vibrations are maximized at a resonance frequency, and said instrument produces an output signal;
j) finding the frequency at which the output signal is maximized, this frequency being the resonance frequency corresponding to the mode shape;
k) changing the mode shape image to that of the next mode to be measured and repeating steps d) to j) to measure the resonance frequency for each mode; and
l. after each resonance frequency is detected, estimating the elastic properties of the sample using an inversion algorithm and the model.

22. The method of claim 21 wherein the temporal modulation is defined by a harmonic signal in the form of at least one frequency.

23. The method of claim 21 wherein the sample has a geometry, boundary conditions, elastic properties, and mass density, and the model predicts the elastic resonance frequencies and mode shapes of a sample given the geometry, boundary conditions, elastic properties, and mass density of the sample.

24. The method of claim 21 wherein the model is solved using a numerical simulation where the spatial domain is discretized using global interpolation functions.

25. The method of claim 21 wherein the model is a numerical simulation where the spatial domain is discretized using local interpolation functions.

26. The method of claim 21 wherein the geometry of the sample is used for analytical calculation of resonance frequencies and mode shapes.

27. The method of claim 21 wherein the sample is below 1 mm in size and has a low Q-factor.
